(19) United States
(12) Patent Application Publication
(10) Pub. No.: US 2024/0305255 A1
(43) Pub. Date: Sep. 12, 2024

(54) POWER AMPLIFIER

(71) Applicant: Samsung Electro-Mechanics Co., Ltd., Suwon-si (KR)

(72) Inventors: Geunyong LEE, Suwon-si (KR); Seungchul PYO, Suwon-si (KR)

(73) Assignee: Samsung Electro-Mechanics Co., Ltd., Suwon-si (KR)

(21) Appl. No.: 18/520,795

(22) Filed: Nov. 28, 2023

(30) Foreign Application Priority Data
Mar. 7, 2023 (KR) 10-2023-0029933

(51) Int. Cl. H03F 3/24; H03F 3/72

(52) U.S. Cl. CPC H03F 3/245; H03F 3/72; H03F 2200/451; H03F 2203/7206

(57) ABSTRACT

A power amplifier includes a first power transistor configured to amplify an input radio-frequency (RF) signal, and output the amplified input RF signal as an output RF signal; a first transistor including a first terminal configured to provide a first bias current to the first power transistor; and a first linearizing circuit connected between a terminal of the first power transistor from which the output RF signal is output and the first terminal of the first transistor and configured to couple a portion of the output RF signal to the first terminal of the first transistor.

### CROSS-REFERENCE TO RELATED APPLICATIONS

This application claims the benefit under 35 USC 119(a) of Korean Patent Application No. 10-2023-0029933 filed on Mar. 7, 2023, in the Korean Intellectual Property Office, the entire disclosure of which is incorporated herein by reference for all purposes.

### BACKGROUND

### 1. Field

The present disclosure relates to a power amplifier.

### 2. Description of Related Art

With the evolution of communications standards, wireless communication systems have adopted various digital modulation and demodulation techniques. The existing CDMA (Code-Division Multiple Access) communication systems are adopting the QPSK (Quadrature Phase Shift Keying) technique, and wireless LANs according to IEEE standards for communications are adopting the OFDM (Orthogonal Frequency-Division Multiplexing) technique. Furthermore, LTE (Long-Term Evolution) and LTE Advanced, which are the standards in 3GPP, are adopting the QPSK, QAM (Quadrature Amplitude Modulation), and OFDM techniques. These wireless communication standards use linear modulation schemes in which the magnitude or phase of a transmission signal is required to be maintained during transmission.

On the other hand, in the recent standard for sub-6 GHz 5G, the linearity of communication systems has been becoming more important as the channel bandwidth has been increasing. Furthermore, high output power has been needed for power amplifiers to be included in communication systems. Accordingly, the linearity of power amplifiers relative to the output power has been becoming more important.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a power amplifier includes a first power transistor configured to amplify an input radio-frequency (RF) signal, and output the amplified input RF signal as an output RF signal; a first transistor including a first terminal configured to provide a first bias current to the first power transistor; and a first linearizing circuit connected between a terminal of the first power transistor from which the output RF signal is output and the first terminal of the first transistor and configured to couple a portion of the output RF signal to the first terminal of the first transistor.

The power amplifier may further includes a second power transistor configured to amplify the output RF signal of the first power transistor; a second transistor including a first terminal configured to provide a second bias current to the second power transistor; and a second linearizing circuit connected between a terminal of the first power transistor to which the input RF signal is input and the first terminal of the second transistor and configured to couple a portion of the input RF signal to the first terminal of the second transistor.

The first linearizing circuit may include a capacitor connected between the terminal of the first power transistor from which the output RF signal is output and the first terminal of the first transistor.

The first linearizing circuit may further include a resistor connected in series with the capacitor between the terminal of the first power transistor from which the output RF signal is output and the first terminal of the first transistor.

The first linearizing circuit may further include an inductor connected in series with the capacitor between the terminal of the first power transistor from which the output RF signal is output and the first terminal of the first transistor.

The power amplifier may further include a resistor connected between the first terminal of the first transistor and an input terminal of the first power transistor.

The power amplifier may further include a capacitor connected between a base of the first transistor and a ground, wherein the first terminal of the first transistor may be an emitter of the first transistor.

In another general aspect, a power amplifier includes a first power transistor configured to amplify an input radio-frequency (RF) signal and output the amplified input RF signal as an output RF signal; a first bias circuit configured to generate a first bias current for biasing the first power transistor and including a first terminal from which the first bias current is output; a second power transistor configured to amplify the output RF signal; a second bias circuit configured to generate a second bias current for biasing the second power transistor and including a first terminal from which the second bias current is output; and a first linearizing circuit including an input terminal connected to a terminal of the first power transistor from which the output RF signal is output and configured to couple a portion of the output RF signal, wherein the first linearizing circuit is further configured to provide the coupled output RF signal to the first terminal of the first bias circuit in a first power mode, and provide the coupled output RF signal to the first terminal of the second bias circuit in a second power mode.

The power amplifier may further include a second linearizing circuit including an input terminal connected to a terminal of the first power transistor to which the input RF signal is input and configured to couple a portion of the input RF signal, wherein the second linearizing circuit is further configured to provide the coupled input RF signal to the first terminal of the second bias circuit in the first power mode, and provide the coupled input RF signal to the first terminal of the first bias circuit in the second power mode.

An input power of the input RF signal of the first power transistor in the first power mode may be lower than the input power of the input RF signal of the first power transistor in the second power mode.

The power amplifier may further include a first switch connected between an output terminal of the first linearizing circuit and the first terminal of the first bias circuit; a second switch connected between the output terminal of the first linearizing circuit and the first terminal of the second bias circuit; a third switch connected between an output terminal of the second linearizing circuit and the first terminal of the second bias circuit; and a fourth switch connected between the output terminal of the second linearizing circuit and the first terminal of the first bias circuit.

The first switch and the third switch may be configured to be turned on in the first power mode, and the second switch and the fourth switch may be configured to be turned off in the first power mode, and the second switch and the fourth switch may be further configured to be turned on in the second power mode, and the first switch and the third switch may be further configured to be turned off in the second power mode.

The power amplifier may further include a first resistor connected between the first terminal of the first bias circuit and an input terminal of the first power transistor; and a second resistor connected between the first terminal of the second bias circuit and an input terminal of the second power transistor.

The first bias circuit may include a first transistor, and an emitter of the first transistor may be the first terminal of the first bias circuit, and the second bias circuit may include a second transistor, and an emitter of the second transistor may be the first terminal of the second bias circuit.

In another general aspect, a power amplifier includes a first power transistor including an input terminal and an output terminal, the input terminal of the first power transistor being configured to receive an input radio-frequency (RF) signal, and the first power transistor being configured to amplify the input radio-frequency RF signal and output the amplified input RF signal as an output RF signal from the output terminal of the first power transistor; a first transistor including a first terminal configured to provide a first bias current to the first power transistor; and a first linearizing circuit connected between the output terminal of the first power transistor and the first terminal of the first transistor and configured to compensate for a drop in a voltage of the input terminal of the first power transistor as an output power of the output RF signal of the first power transistor increases based on the output RF signal of the first power transistor.

The first linearizing circuit may be further configured to compensate for the drop in the voltage of the input terminal of the first power transistor by coupling a portion of the output RF signal of the first power transistor to the first terminal of the first transistor.

The power amplifier may further include a second power transistor including an input terminal and an output terminal, the input terminal of the second power transistor being configured to receive the output RF signal of the first power transistor, and the second power transistor being configured to amplify the output RF signal of the first power transistor and output the amplified output RF signal as a final output RF signal from the output terminal of the second power transistor; a second transistor including a first terminal configured to provide a second bias current to the second power transistor; and a second linearizing circuit connected between the input terminal of the first power transistor and the first terminal of the second transistor and configured to compensate for a drop in a voltage of the input terminal of the second power transistor as an output power of the final output RF signal of the second power transistor increases based on the input RF signal of the first power transistor.

The second linearizing circuit may be further configured to compensate for the drop in the voltage of the input terminal of the second power transistor by coupling a portion of the input RF signal of the first power transistor to the first terminal of the second transistor.

The power amplifier may further include a first switch connected between an output terminal of the first linearizing circuit and the first terminal of the first transistor; a second switch connected between the output terminal of the first linearizing circuit and the first terminal of the second transistor; a third switch connected between an output terminal of the second linearizing circuit and the first terminal of the second transistor; and a fourth switch connected between the output terminal of the second linearizing circuit and the first terminal of the first transistor.

The first switch and the third switch may be configured to be turned on in a first power mode, and the second switch and the fourth switch are configured to be turned off in the first power mode, the second switch and the fourth switch may be further configured to be turned on in the second power mode, the first switch and the third switch may be further configured to be turned off in the second power mode, and an input power of the input RF signal of the first power transistor in the first power mode may be lower than the input power of the input RF signal of the first power transistor in the second power mode.

Other features and aspects will be apparent from the following detailed description, the drawings, and the claims.

### BRIEF DESCRIPTION OF DRAWINGS

FIG. 1 is a drawing illustrating a power amplifier according to an embodiment.

FIG. 2 is a drawing illustrating a bias circuit of the power amplifier of FIG. 1.

FIG. 3A is a drawing illustrating an example of a linearizing circuit of the power amplifier of FIG. 1.

FIG. 3B is a drawing illustrating another example of the linearizing circuit of the power amplifier of FIG. 1.

FIG. 3C is a drawing illustrating another example of the linearizing circuit of the power amplifier of FIG. 1.

FIG. 4 is a drawing illustrating a power amplifier according to another embodiment.

FIG. 5 is a drawing illustrating a power amplifier according to another embodiment.

FIG. 6A is a drawing illustrating the operation of a power amplifier of FIG. 5 in a first power mode.

FIG. 6B is a drawing illustrating the operation of the power amplifier of FIG. 5 in a second power mode.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The use of the term “may” with respect to an example or embodiment, e.g., as to what an example or embodiment may include or implement, means that at least one example or embodiment exists in which such a feature is included or implemented, while all examples and embodiments are not necessarily limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

In this application, an RF signal may have a format according to Wi-Fi (such as IEEE 802.11 family, etc.), WiMAX (IEEE 802.16 family, etc.), IEEE 802.20, LTE (Long-Term Evolution), EV-DO, HSDPA, HSUPA, HSPA, HSPA+, EDGE, GSM, GPS, GPRS, CDMA, TDMA, DECT, Bluetooth, 3G, 4G, 5G, and any other wireless and wired communication protocols designated hereafter, but is not limited thereto.

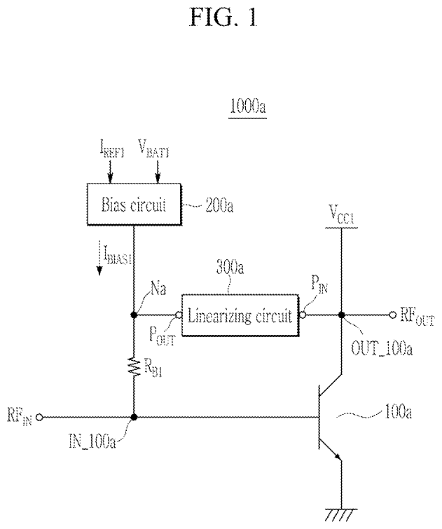

FIG. 1 is a drawing illustrating a power amplifier according to an embodiment.

Referring to FIG. 1, a power amplifier 1000a may include a power transistor 100a, a bias circuit 200a, and a linearizing circuit 300a.

In FIG. 1, an input RF signal input to the power amplifier 1000a is denoted by “RF_{IN}”, and an output RF signal output from the power amplifier 1000a is denoted by “RF_{OUT}”.

The power transistor 100a may include an input terminal IN_100a and an output terminal OUT_100a. The input terminal IN_100a may be a base of the power transistor 100a, and the output terminal OUT_100a may be a collector of the power transistor 100a. The power transistor 100a may amplify a power of the input RF signal RF_{IN} input to the input terminal IN_100a (i.e., the base), and output the amplifier power through the output terminal OUT_100a (i.e., the collector). In other words, the input terminal IN_100a of the power transistor 100a may receive the input RF signal RF_{IN}, and the output terminal OUT_100a of the power transistor 100a may output the output RF signal RF_{OUT}. An emitter of the power transistor 100a may be connected to a ground. Although not shown in FIG. 1, a resistor may be additionally connected between the emitter of the power transistor 100a and the ground. Furthermore, the collector of the power transistor 100a may be connected to a power voltage V_{CC1}, and the power transistor 100a may be operated by the power voltage V_{CC1}. Alternatively, the collector of the power transistor 100a may be connected to the power voltage V_{CC1} through an inductor (not shown in FIG. 1) that performs an RF choke function.

The power transistor 100a may be any of various types of transistors such as heterojunction bipolar transistors (HBTs), bipolar junction transistors (BJTs), and insulated gate bipolar transistors (IGBTs). Furthermore, although the power transistor 100a is shown in FIG. 1 as being an n-type transistor, it may be replaced with a p-type transistor.

The bias circuit 200a may receive a reference current I_{REF1} and a power voltage V_{BAT1} from outside the power amplifier 1000a. The power voltage V_{BAT1} may be a voltage supplied from a battery. The bias circuit 200a may generate a bias current I_{BIAS1} required for the power transistor 100a based on the reference current I_{REF1} and the power voltage V_{BAT1}. The bias current I_{BIAS1} may be supplied to the input terminal IN_100a of the power transistor 100a through a resistor R_{B1}, and a bias level (bias point) of the power transistor 100a may be set by the bias current I_{BIAS1}.

The power amplifier 1000a may further include the resistor R_{B1}. The resistor R_{B1} may be connected between the bias circuit 200a and the input terminal IN_100a of the power transistor 100a. The resistor R_{B1} may be a ballast resistor that improves heat dissipation characteristics of the power amplifier 1000a. In FIG. 1, a node at which the bias circuit 200a and the resistor R_{B1} are connected to each other is denoted by “Na”. Although the resistor R_{B1} is shown in FIG. 1 as a separate component not included in the bias circuit 200a, the resistor R_{B1} may be included in the bias circuit 200a.

The linearizing circuit 300a may include an input terminal P_{IN} and an output terminal P_{OUT}. The input terminal P_{IN} of the linearizing circuit 300a may be connected to the output terminal OUT_100a of the power transistor 100a, and the output terminal P_{OUT} of the linearizing circuit 300a may be connected to the node Na. In other words, the linearizing circuit 300a may be connected between the output terminal OUT_100a of the power transistor 100a and the node Na. The linearizing circuit 300a can improve the linearity of the power transistor 100a relative to an output power of the power transistor 100a. As the output power (i.e., a gain) of the power transistor 100a increases, a drop in the voltage of the base of the power transistor 100a (a base voltage drop) may occur. In this case, the linearizing circuit 300a can compensate for the drop in the voltage of the base of the power transistor 100a based on the output RF signal RF_{OUT}.

As the output power (gain) of the power transistor 100a increases, the bias current I_{BIAS1} may increase. An increase in the bias current I_{BIAS1} may cause a rise in a voltage difference between both ends of the resistor R_{B1}, which may cause a drop in the base voltage of the power transistor 100a. The linearizing circuit 300a can compensate for the drop in the base voltage of the power transistor 100a. The linearizing circuit 300a may couple an output RF signal RF_{OUT}, not an input RF signal RF_{IN}. By the linearizing circuit 300a, a portion of the output RF signal RF_{OUT} may be coupled and output to the node Na. Hereinafter, an output RF signal RF_{OUT} that is coupled will be referred to as a “coupled output RF signal”. The specific configuration and operation of the linearizing circuit 300a will be described below in more detail.

Although not shown in FIG. 1, the power amplifier 1000a may further include a coupling capacitor connected to the input terminal IN_100a (i.e., the base) of the power transistor 100a. The coupling capacitor may perform a function of blocking a direct current (DC) component of the input RF signal RF_{IN}.

Furthermore, although not shown in FIG. 1, the power amplifier 1000a may further include an input matching network and an output matching network. The input matching network may be connected to the input terminal IN_100a of the power transistor 100a, and may perform impedance matching between the input RF signal RF_{IN} and the power transistor 100a. The output matching network may be connected to the output terminal OUT_100a (i.e., the collector) of the power transistor 100a, and may perform impedance matching between the output RF signal RF_{OUT} and a next stage (i.e., a next stage of the power amplifier 1000a). Each of the input matching network and the output matching network may be implemented with at least one combination of resistors, inductors, and capacitors.

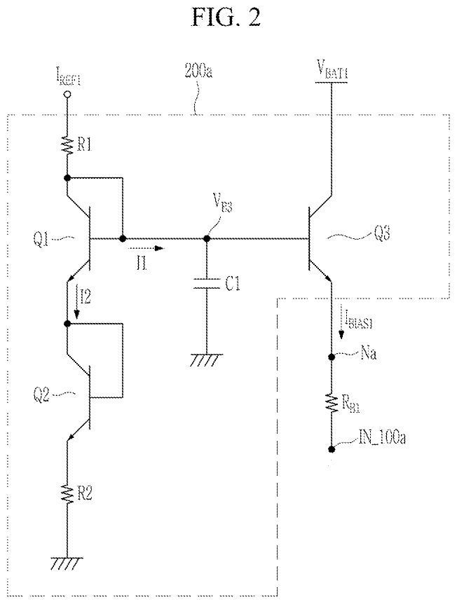

FIG. 2 is a drawing illustrating the bias circuit of FIG. 1.

Referring to FIG. 2, the bias circuit 200a may include a transistor Q1, a transistor Q2, a transistor Q3, a resistor R1, a resistor R2, and a capacitor C1.

The transistors Q1 to Q3 may be any of various types of transistors such as heterojunction bipolar transistors (HBTs), bipolar junction transistors (BJTs), and insulated gate bipolar transistors (IGBTs). Furthermore, although the transistors Q1 to Q3 are shown in FIG. 2 as being n-type transistors, they may be replaced with p-type transistors. A base of each of the transistors Q1 to Q3 serves as a control terminal of the corresponding transistor, so it will also referred to as a “control terminal. A collector of each of the transistors Q1 to Q3 is one terminal of the corresponding transistor, so it will also be referred to as a “first terminal” or a “second terminal”. An emitter of each of the transistors Q1 to Q3 is another terminal of the corresponding transistor, so it will also be referred to as a “second terminal” or a “first terminal”.

The base and the collector of the transistor Q1 may be connected to each other, and the collector of the transistor Q1 may receive the reference current I_{REF1} through the resistor R1. Thus, the transistor Q1 may have a diode-connected structure. The transistor Q1 serves to sink a current I2 from the reference current I_{REF1}. The reference current I_{REF1} may be a current source.

The base and the collector of the transistor Q2 may be connected to each other, and the collector of the transistor Q2 may be connected to the emitter of the transistor Q1. Thus the transistor Q2 may have a diode-connected structure, and the emitter of the transistor Q2 may be connected to the ground.

Furthermore, the resistor R2 may be connected between the emitter of the transistor Q2 and the ground.

The collector of the transistor Q3 may be connected to the power voltage V_{BAT1}, and the base of the transistor Q3 may be connected to the base of the transistor Q1. In FIG. 2, the base voltage of the transistor Q3 is denoted by ‘V_{B3}’. Furthermore, the emitter of the transistor Q3 may be connected to the input terminal IN_100a of the power transistor 100a through the resistor R_{B1}. In other words, the emitter of the transistor Q3 may supply the bias current I_{BIAS1} to the power transistor 100a through the resistor R_{B1}. As shown in FIG. 2, the node Na described with reference to FIG. 1 may be a node at which the transistor Q3 and the resistor R_{B1} are connected to each other.

The capacitor C1 may be connected between the base of the transistor Q3 and the ground. The capacitor C1 may serve to reduce the impedance of the transistor Q3 while stabilizing the base voltage V_{B3} of the transistor Q3.

The reference current I_{REF1} may be divided into a current I1 and the current I2, and the current I1 may be input to the base of the transistor Q3. Accordingly, the bias current I_{BIAS1} may be determined depending on the current I1. Furthermore, the bias current I_{BIAS1} may be determined depending on the base voltage V_{B3} of the transistor Q3. As an example, as the base voltage V_{B3} of the transistor Q3 increases, the bias current I_{BIAS1} may increase.

As described with reference to FIG. 1, the linearizing circuit 300a may output a coupled output RF signal to the node Na. The coupled output RF signal is input to the emitter of the transistor Q3, causing the bias current I_{BIAS1} to increase. By the increase in the bias current I_{BIAS1}, a drop in the base voltage of the power transistor 100a can be compensated. In other words, the linearizing circuit 300a can compensate for a drop in the base voltage of the power transistor 100a.

Depending on the magnitude of the coupled output RF signal, the extent to which the drop in the base voltage of the power transistor 100a is compensated may vary. As the magnitude of the coupled output RF signal increases, a drop in the base voltage of the power transistor 100a can be more greatly compensated. Since the magnitude (power) of the output RF signal RF_{OUT} is larger than the magnitude of the input RF signal RF_{IN}, the linearizing circuit 300a may couple the output RF signal RF_{OUT}, not the input RF signal RF_{IN}. Accordingly, the linearizing circuit 300a can further improve the linearity by compensating more greatly for a drop in the base voltage of the power transistor 100a.

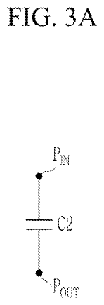

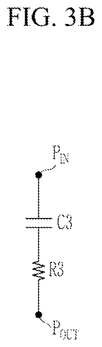

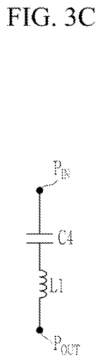

Hereinafter, various examples of the linearizing circuit 300a will be described with respect to following FIG. 3A to FIG. 3C.

FIG. 3A is a drawing illustrating an example of a linearizing circuit of FIG. 1.

Referring to FIG. 3A, the linearizing circuit 300a may include the input terminal P_{IN} and the output terminal P_{OUT}. The input terminal P_{IN} may correspond to the output terminal of the power transistor 100a, and the output terminal P_{OUT} may correspond to the node Na. The input terminal P_{IN} of the linearizing circuit 300a may receive an RF signal to be coupled, and the output terminal P_{OUT} of the linearizing circuit 300a may output a coupled RF signal.

The example of the linearizing circuit 300a may include a capacitor C2. The capacitor C2 may be connected between the input terminal P_{IN} and the output terminal P_{OUT}. The capacitor C2 may couple a portion of an output RF signal RF_{OUT} input to the input terminal P_{IN}, and output the coupled RF signal to the output terminal P_{OUT} (i.e., the node Na).

FIG. 3B is a drawing illustrating another example of the linearizing circuit of FIG. 1.

Referring to FIG. 3B, another example of the linearizing circuit 300a may include a capacitor C3 and a resistor R3.

One terminal of the capacitor C3 may be connected to the input terminal P_{IN}, and the resistor R3 may be connected between the other terminal of the capacitor C3 and the output terminal P_{OUT}. Alternatively, the positions of the capacitor C3 and the resistor R3 may be exchanged with each other. In other words, one terminal of the resistor R3 may be connected to the input terminal P_{IN}, and the capacitor C3 may be connected between the other terminal of the resistor R3 and the output terminal P_{OUT}.

In other words, between the output terminal OUT_100a of the power transistor 100a and the node Na, the capacitor C3 and the resistor R3 may be connected in series with each other. The capacitor C3 and the resistor R3 may couple a portion of the output RF signal RF_{OUT} input to the input terminal P_{IN}, and output the coupled RF signal to the output terminal P_{OUT} (i.e., the node Na).

FIG. 3C is a drawing illustrating another example of the linearizing circuit of FIG. 1.

Referring to FIG. 3C, another example of the linearizing circuit 300a may include a capacitor C4 and an inductor L1.

One terminal of the capacitor C4 may be connected to the input terminal P_{IN}, and the inductor L1 may be connected between the other terminal of the capacitor C4 and the output terminal P_{OUT}. Alternatively, the positions of the capacitor C4 and the inductor L1 may be exchanged with each other. In other words, one terminal of the inductor L1 may be connected to the input terminal P_{IN}, and the capacitor C4 may be connected between the other terminal of the inductor L1 and the output terminal P_{OUT}.

Consequently, between the output terminal OUT_100a of the power transistor 100a and the node Na, the capacitor C4 and the inductor L1 may be connected in series with each other. The capacitor C4 and the inductor L1 may couple a portion of the output RF signal RF_{OUT} input to the input terminal P_{IN}, and output the coupled RF signal to the node Na.

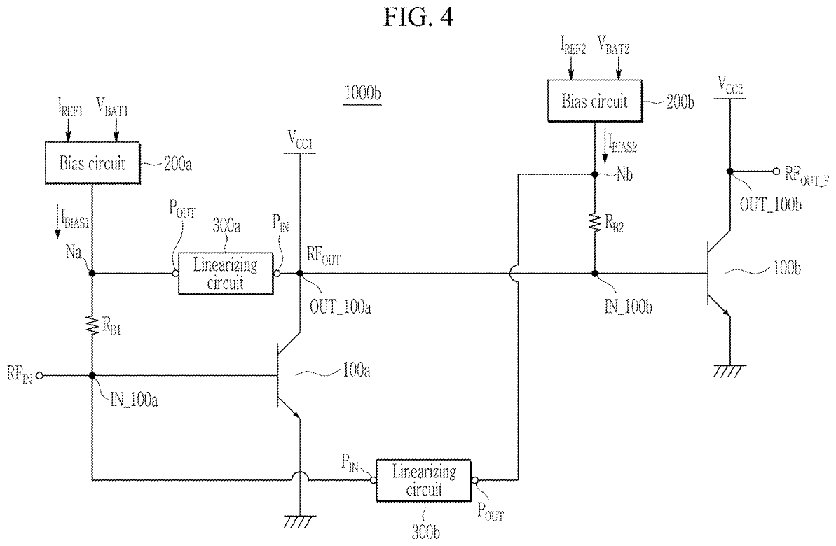

FIG. 4 is a drawing illustrating a power amplifier according to another embodiment.

Referring to FIG. 4, a power amplifier 1000b has a multi-stage power amplifier structure. The power amplifier 1000b may further include a power transistor 100b, a bias circuit 200b, and a linearizing circuit 300b, in addition to components identical to those in the power amplifier 1000a in FIG. 1. The power transistor 100a, the bias circuit 200a, and the linearizing circuit 300a constitute a first-stage power amplifier, and have the same configuration as in FIG. 1. Furthermore, the power transistor 100b, the bias circuit 200b, and the linearizing circuit 300b constitute a second-stage power amplifier, which will be described below.

The power transistor 100b may include an input terminal IN_100b and an output terminal OUT_100b. The input terminal IN_100b may be a base of the power transistor 100b, and the output terminal OUT_100b may be a collector of the power transistor 100b. The input terminal IN_100b of the power transistor 100b may be connected to the output terminal OUT_100a of the power transistor 100a. The power transistor 100b may amplify the output RF signal RF_{OUT} of the power transistor 100a, and output a final output RF signal RF_{OUT} F to the output terminal OUT_100b. An emitter of the power transistor 100b may be connected to the ground. Although not shown in FIG. 4, a resistor may be additionally connected between the emitter of the power transistor 100b and the ground. Although not shown in FIG. 4, a coupling capacitor may be additionally connected between the output terminal OUT_100a of the power transistor 100a and the input terminal IN_100b of the power transistor 100b. Furthermore, the collector of the power transistor 100b may be connected to a power voltage V_{CC2}, and the power transistor 100b may be operated by the power voltage V_{CC2}. Alternatively, the collector of the power transistor 100b may be connected to the power voltage V_{CC2} through an inductor (not shown in FIG. 4) that performs an RF choke function.

The power transistor 100b may be any of various types of transistors such as heterojunction bipolar transistors (HBTs), bipolar junction transistors (BJTs), and insulated gate bipolar transistors (IGBTs). Furthermore, although the power transistor 100b is shown in FIG. 4 as being an n-type transistor, it may be replaced with a p-type transistor.

The bias circuit 200b may receive a reference current I_{REF2} and a power voltage V_{BAT2} from outside the power amplifier 1000b. The power voltage V_{BAT2} may be a voltage supplied from a battery. The bias circuit 200b may generate a bias current I_{BIAS2} required for the power transistor 100b based on the reference current I_{REF2} and the power voltage V_{BAT2}. The bias current I_{BIAS2} may be supplied to the input terminal IN_100b of the power transistor 100b through a resistor R_{B2}, and a bias level (bias point) of the power transistor 100b may be set by the bias current I_{BIAS2}. Furthermore, the bias circuit 200b may have the same configuration as that of the bias circuit 200a in FIG. 2 except that the reference current I_{REF2} and the power voltage V_{BAT2} are used in place of the reference current I_{REF1} and the power voltage V_{BAT1}.

The power amplifier 1000b may further include the resistor R_{B2}. The resistor R_{B2} may be connected between the bias circuit 200b and the input terminal IN_100b of the power transistor 100b. The resistor R_{B2} may be a ballast resistor that improves heat dissipation characteristics of the power amplifier 1000b. In FIG. 4, a node at which the bias circuit 200b and the resistor R_{B2} are connected to each other is denoted by ‘Nb”. Although the resistor R_{B2} is shown in FIG. 4 as a separate component not included in the bias circuit 200b, the resistor R_{B2} may be included in the bias circuit 200b.

The linearizing circuit 300b may include an input terminal P_{IN} and an output terminal P_{OUT}. The input terminal P_{IN} of the linearizing circuit 300b may be connected to the input terminal IN_100a of the power transistor 100a, and the output terminal P_{OUT} of the linearizing circuit 300b may be connected to the node Nb. In other words, the linearizing circuit 300b may be connected between the input terminal IN_100a of the power transistor 100a and the node Nb. The linearizing circuit 300b can improve the linearity of the power transistor 100b relative to an output power of the power transistor 100b. As the output power (i.e., a gain) of the power transistor 100b increases, a drop in a voltage of the base of the power transistor 100b (a base voltage drop) may occur. In this case, the linearizing circuit 300b can compensate for the drop in the voltage of the base of the power transistor 100b based on the input RF signal RF_{IN}. In other words, the linearizing circuit 300b may couple a portion of the input RF signal RF_{IN}, and output the coupled RF signal to the node Nb, thereby compensating for the drop in the base voltage of the power transistor 100b. Various examples of the linearizing circuit 300b may have the same configurations as those in FIG. 3A to FIG. 3C. The input terminal P_{IN} of the linearizing circuit 300b may correspond to the input terminal IN_100a of the power transistor 100a, and the output terminal P_{OUT} of the linearizing circuit 300b may correspond to the node Nb.

Although not shown in FIG. 4, a coupling capacitor may be additionally connected between the output terminal OUT_100a of the power transistor 100a and the input terminal IN_100b of the power transistor 100b. Furthermore, between the output terminal OUT_100a of the power transistor 100a and the input terminal IN_100b of the power transistor 100b, an interstage matching network may be additionally connected.

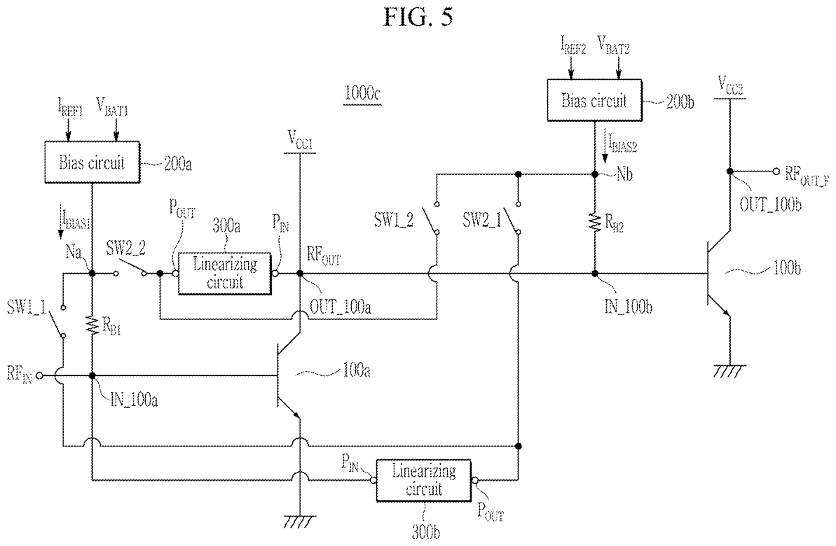

FIG. 5 is a drawing illustrating a power amplifier according to another embodiment.

Referring to FIG. 5, a power amplifier 1000c is similar to the power amplifier 1000b in FIG. 5 except that it further includes a plurality of switches configured to be switched depending on a power mode of the power amplifier 1000c. The power amplifier 1000c may further include a switch SW1_1, a switch SW1_2, a switch SW2_1, and a switch SW2_2 in addition to components identical to those in the power amplifier 1000b in FIG. 4.

The input terminal P_{IN} of the linearizing circuit 300a may be connected to the output terminal OUT_100a of the power transistor 100a, and the linearizing circuit 300a may couple a portion of the output RF signal RF_{OUT}.

The switch SW2_2 may be connected between the output terminal P_{OUT} of the linearizing circuit 300a and the node Na. The switch SW1_2 may be connected between the output terminal P_{OUT} of the linearizing circuit 300a and the node Nb.

The input terminal P_{IN} of the linearizing circuit 300b may be connected to the input terminal IN_100a of the power transistor 100a, and the linearizing circuit 300b may couple a portion of the input RF signal RF_{IN}.

The switch SW1_1 may be connected between the output terminal P_{OUT} of the linearizing circuit 300b and the node Na. The switch SW2_1 may be connected between the output terminal P_{OUT} of the linearizing circuit 300b and the node Nb.

The switches SW1_1, SW1_2, SW2_1, and SW2_2 may be switched depending on a power mode of the power amplifier 1000c. The switch SW2_1 and the switch SW2_2 may be turned on and the switch SW1_1 and the switch SW1_2 may be turned off in a first power mode, and the switch SW1_1 and the switch SW1_2 may be turned on and the switch SW2_1 and the switch SW2_2 may be turned off in a second power mode. The first power mode is a mode for generating an output power (a gain) lower than an output power (a gain) in the second power mode. As an example, the first power mode may be a low-power mode (LPM), and the second power mode may be a high-power mode (HPM).

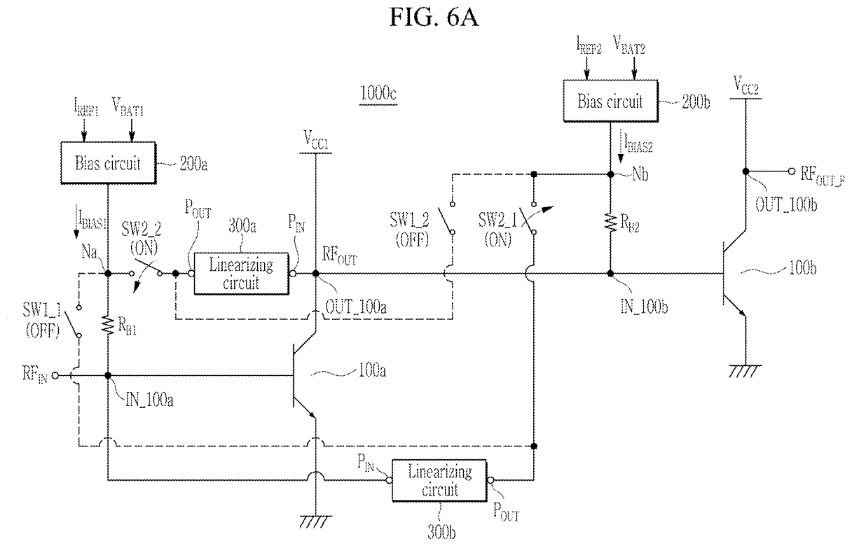

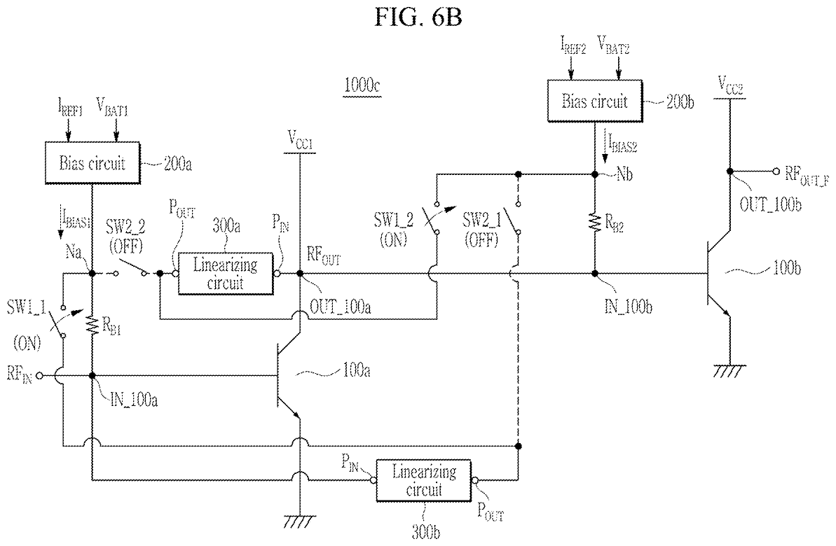

FIG. 6A is a drawing illustrating the operation of the power amplifier of FIG. 5 in the first power mode.

Referring to FIG. 6A, in the first power mode, the switch SW2_1 and the switch SW2_2 are turned on, and the switch SW1_1 and the switch SW1_2 are turned off.

By turning on the switch SW2_2, the output terminal P_{OUT} of the linearizing circuit 300a may be connected to the node Na. Accordingly, the linearizing circuit 300a may couple a portion of the output RF signal RF_{OUT}, and output the coupled RF signal to the node Na. Since the magnitude (power) of the input RF signal RF_{IN} in the first power mode is smaller than the magnitude (power) of the input RF signal RF_{IN} in the second power mode, the linearizing circuit 300a may couple the output RF signal RF_{OUT} that is an amplified signal. In other words, since the magnitude (power) of the output RF signal RF_{OUT} is larger than the magnitude (power) of the input RF signal RF_{IN}, the linearizing circuit 300a may couple the output RF signal RF_{OUT}, not the input RF signal RF_{IN}. Accordingly, the linearizing circuit 300a can compensate more greatly for a drop in the base voltage of the power transistor 100a.

By turning on the switch SW2_1, the output terminal P_{OUT} of the linearizing circuit 300b may be connected to the node Nb. Accordingly, the linearizing circuit 300b may couple a portion of the input RF signal RF_{IN}, and output the coupled RF signal to the node Nb. In other words, the linearizing circuit 300b may couple a portion of the input RF signal RF_{IN}, and output the coupled RF signal to the node Nb, thereby compensating for a drop in the base voltage of the power transistor 100b.

FIG. 6B is a drawing illustrating the operation of the power amplifier of FIG. 5 in the second power mode.

Referring to FIG. 6B, in the second power mode, the switch SW1_1 and the switch SW1_2 are turned on, and the switch SW2_1 and the switch SW2_2 are turned off.

By turning on the switch SW1_1, the output terminal P_{OUT} of the linearizing circuit 300b may be connected to the node Na. Accordingly, the linearizing circuit 300b may couple a portion of the input RF signal RF_{IN}, and output the coupled RF signal to the node Na. Since the magnitude (power) of the input RF signal RF_{IN} in the second power mode is larger than magnitude (power) of the input RF signal RF_{IN} in the first power mode, the linearizing circuit 300b may couple the input RF signal RF_{IN}, thereby improving the linearity of the power amplifier 1000c. Accordingly, the linearizing circuit 300b can effectively compensate for a drop in the base voltage of the power transistor 100a.

By turning on the switch SW1_2, the output terminal P_{OUT} of the linearizing circuit 300a may be connected to the node Nb. Accordingly, the linearizing circuit 300a may couple a portion of the output RF signal RF_{OUT}, and output the coupled RF signal to the node Nb. In other words, the linearizing circuit 300a may couple a portion of the output RF signal RF_{OUT}, and output the coupled RF signal to the node Nb, thereby compensating for a drop in the base voltage of the power transistor 100b.

Accordingly, the power amplifier 1000c can effectively improve the linearity of the power amplifier 1000c by adjusting an RF signal to be coupled depending on the power mode of the power amplifier 1000c.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power amplifier comprising:
a first power transistor configured to amplify an input radio-frequency (RF) signal, and output the amplified input RF signal as an output RF signal;
a first transistor comprising a first terminal configured to provide a first bias current to the first power transistor; and
a first linearizing circuit connected between a terminal of the first power transistor from which the output RF signal is output and the first terminal of the first transistor and configured to couple a portion of the output RF signal to the first terminal of the first transistor.

2. The power amplifier of claim 1, further comprising:
a second power transistor configured to amplify the output RF signal of the first power transistor;
a second transistor comprising a first terminal configured to provide a second bias current to the second power transistor; and
a second linearizing circuit connected between a terminal of the first power transistor to which the input RF signal is input and the first terminal of the second transistor and configured to couple a portion of the input RF signal to the first terminal of the second transistor.

3. The power amplifier of claim 1, wherein the first linearizing circuit comprises a capacitor connected between the terminal of the first power transistor from which the output RF signal is output and the first terminal of the first transistor.

4. The power amplifier of claim 3, wherein the first linearizing circuit further comprises a resistor connected in series with the capacitor between the terminal of the first power transistor from which the output RF signal is output and the first terminal of the first transistor.

5. The power amplifier of claim 3, wherein the first linearizing circuit further comprises an inductor connected in series with the capacitor between the terminal of the first power transistor from which the output RF signal is output and the first terminal of the first transistor.

6. The power amplifier of claim 1, further comprising a resistor connected between the first terminal of the first transistor and an input terminal of the first power transistor.

7. The power amplifier of claim 6, further comprising a capacitor connected between a base of the first transistor and a ground,
wherein the first terminal of the first transistor is an emitter of the first transistor.

8. A power amplifier comprising:
a first power transistor configured to amplify an input radio-frequency (RF) signal and output the amplified input RF signal as an output RF signal;
a first bias circuit configured to generate a first bias current for biasing the first power transistor and comprising a first terminal from which the first bias current is output;
a second power transistor configured to amplify the output RF signal;
a second bias circuit configured to generate a second bias current for biasing the second power transistor and comprising a first terminal from which the second bias current is output; and
a first linearizing circuit comprising an input terminal connected to a terminal of the first power transistor from which the output RF signal is output and configured to couple a portion of the output RF signal,
wherein the first linearizing circuit is further configured to:
provide the coupled output RF signal to the first terminal of the first bias circuit in a first power mode, and
provide the coupled output RF signal to the first terminal of the second bias circuit in a second power mode.

9. The power amplifier of claim 8, further comprising a second linearizing circuit comprising an input terminal connected to a terminal of the first power transistor to which the input RF signal is input and configured to couple a portion of the input RF signal,
wherein the second linearizing circuit is further configured to:
provide the coupled input RF signal to the first terminal of the second bias circuit in the first power mode, and
provide the coupled input RF signal to the first terminal of the first bias circuit in the second power mode.

10. The power amplifier of claim 9, wherein an input power of the input RF signal of the first power transistor in the first power mode is lower than the input power of the input RF signal of the first power transistor in the second power mode.

11. The power amplifier of claim 9, further comprising:
a first switch connected between an output terminal of the first linearizing circuit and the first terminal of the first bias circuit;
a second switch connected between the output terminal of the first linearizing circuit and the first terminal of the second bias circuit;
a third switch connected between an output terminal of the second linearizing circuit and the first terminal of the second bias circuit; and
a fourth switch connected between the output terminal of the second linearizing circuit and the first terminal of the first bias circuit.

12. The power amplifier of claim 11, wherein the first switch and the third switch are configured to be turned on in the first power mode, and the second switch and the fourth switch are configured to be turned off in the first power mode, and
the second switch and the fourth switch are further configured to be turned on in the second power mode, and the first switch and the third switch are further configured to be turned off in the second power mode.

13. The power amplifier of claim 9, further comprising:
a first resistor connected between the first terminal of the first bias circuit and an input terminal of the first power transistor; and
a second resistor connected between the first terminal of the second bias circuit and an input terminal of the second power transistor.

14. The power amplifier of claim 13, wherein the first bias circuit comprises a first transistor, and an emitter of the first transistor is the first terminal of the first bias circuit, and
the second bias circuit comprises a second transistor, and an emitter of the second transistor is the first terminal of the second bias circuit.

15. A power amplifier comprising:
a first power transistor comprising an input terminal and an output terminal, the input terminal of the first power transistor being configured to receive an input radio-frequency (RF) signal, and the first power transistor being configured to amplify the input radio-frequency RF signal and output the amplified input RF signal as an output RF signal from the output terminal of the first power transistor;
a first transistor comprising a first terminal configured to provide a first bias current to the first power transistor; and
a first linearizing circuit connected between the output terminal of the first power transistor and the first terminal of the first transistor and configured to compensate for a drop in a voltage of the input terminal of the first power transistor as an input power of the input RF signal of the first power transistor increases based on the output RF signal of the first power transistor.

16. The power amplifier of claim 15, wherein the first linearizing circuit is further configured to compensate for the drop in the voltage of the input terminal of the first power transistor by coupling a portion of the output RF signal of the first power transistor to the first terminal of the first transistor.

17. The power amplifier of claim 15, further comprising:
a second power transistor comprising an input terminal and an output terminal, the input terminal of the second power transistor being configured to receive the output RF signal of the first power transistor, and the second power transistor being configured to amplify the output RF signal of the first power transistor and output the amplified output RF signal as a final output RF signal from the output terminal of the second power transistor;
a second transistor comprising a first terminal configured to provide a second bias current to the second power transistor; and
a second linearizing circuit connected between the input terminal of the first power transistor and the first terminal of the second transistor and configured to compensate for a drop in a voltage of the input terminal of the second power transistor as the input power of the first power transistor increases based on the input RF signal of the first power transistor.

18. The power amplifier of claim 17, wherein the second linearizing circuit is further configured to compensate for the drop in the voltage of the input terminal of the second power transistor by coupling a portion of the input RF signal of the first power transistor to the first terminal of the second transistor.

19. The power amplifier of claim 17, further comprising:
a first switch connected between an output terminal of the first linearizing circuit and the first terminal of the first transistor;
a second switch connected between the output terminal of the first linearizing circuit and the first terminal of the second transistor;
a third switch connected between an output terminal of the second linearizing circuit and the first terminal of the second transistor; and
a fourth switch connected between the output terminal of the second linearizing circuit and the first terminal of the first transistor.

20. The power amplifier of claim 19, wherein the first switch and the third switch are configured to be turned on in a first power mode, and the second switch and the fourth switch are configured to be turned off in the first power mode,
the second switch and the fourth switch are further configured to be turned on in a second power mode, and the first switch and the third switch are further configured to be turned off in the second power mode, and
the input power of the input RF signal of the first power transistor in the first power mode is lower than the input power of the input RF signal of the first power transistor in the second power mode.
